(19) United States
(12) Patent Application Publication
(10) Pub. No.: US 2012/0146661 A1
(43) Pub. Date: Jun. 14, 2012

(54) FAULT INDICATOR CAPACTIVE POWER SOURCE

(76) Inventor: Kirk Thomas, Escondido, CA (US)

(21) Appl. No.: 13/291,060

(22) Filed: Nov. 7, 2011

Related U.S. Application Data
(63) Continuation-in-part of application No. 12/698,953, filed on Feb. 2, 2010.
(60) Provisional application No. 61/410,766, filed on Nov. 5, 2010.

(51) Int. Cl. G01R 31/02

(52) U.S. Cl. 324/542

(57) ABSTRACT

The present invention provides, in at least one embodiment, a fault indicator powered by a capacitive power source. The capacitive power source can be a charged capacitor which can be charged by an electrostatic field and an electromagnetic field around a power line being monitored. The charged capacitor can be an electrochemical double-layer capacitor, a supercapacitor, or an ultracapacitor. These capacitors provide superior energy storage compared to conventional battery power sources.

### CROSS REFERENCE TO RELATED APPLICATIONS

This continuation-in-part application claims the benefit of U.S. patent application Ser. No. 12/698,953, filed on Feb. 2, 2010, and entitled “High Voltage to Low Voltage Inductive Power Supply with Current Sensor,” and the application claims priority under 35 U.S.C. §119(e) to U.S. Provisional Application No. 61/410,766, filed Nov. 5, 2010, and entitled “Microprocessor Controlled Fault Indicator Module Powered by Ultra Capacitor, Double Layer Capacitor, or Super Capacitor,” the disclosures of which are hereby incorporated by reference in their entirety.

### BACKGROUND OF THE INVENTION

1. Field of Invention

The invention relates generally to an electric power distribution system in a wide geographic area and more particularly, to systems and methods of powering a device that detects and records fault conditions at various locations.

2. Description of Related Art

An electric power distribution system delivers electricity from a transmission terminal to consumers. Typically, the electric power distribution system includes medium-voltage power lines (e.g., less than 50 kV), substations, pole-mounted transformers, low-voltage distribution wiring (e.g., less than 1 kV), and meters for billing.

Malfunctions in power distribution systems are often accompanied by transient current surges in certain locations of the system. Typically, a fault condition can be a transient current surge in certain locations of the electric power distribution system. To isolate and diagnose a malfunction, technicians may be dispatched to inspect various locations in the system after the faulted circuit event has occurred. However, because the current surge may have only lasted a short time, hence a transient current surge, the technician would not be able to diagnose the current surges without equipment that recorded the occurrence of these surges.

In response, faulted circuit indicator devices have been developed to record the occurrence of these surges, that is, faulted circuit events, on electric power distribution systems. Faulted circuit indicators are sometimes referred to as fault indicators or FCI's, etc. Various types of fault indicator devices have been developed to record fault conditions, including battery powered fault indicators, test point terminal mounted fault indicators, electro-statically powered fault indicators and electro-magnetically powered fault indicators.

Battery powered fault indicators can be powered with an internal lithium type battery. The energy stored in the battery can be used to power the fault indicator, including the control electronic circuitry which monitors the power lines and the indicator display which conveys the status of the power lines. Batteries used to power fault indicators typically have a capacity between 1.6 and 8.5 amp-hours (Ah), where amp-hour is a common measurement for electrochemical systems such as lithium batteries. One amp-hour is the electric charge transferred by a steady current of one amp for one hour.

Another fault indicator, the test point terminal mounted fault indicator, can be powered via a capacitively coupled test point terminal socket or connectors affixed to the power line.

Another fault indicator, the inductively coupled fault indicator, derives its operating power from the magnetic field surrounding the power line when the power line is energized. Similarly, the electrostatically coupled fault indicator derives its operating power from being capacitively coupled to the electrostatic field surrounding the energized power line.

These four types of fault indicators must be able to display a faulted circuit condition and a normal condition, depending on system status, without ambiguity. Technicians must be able to easily interrogate the state of the device, usually using visual means. The most popular types of displays are brightly colored rotating mechanical flags or LED (light emitting diode) type displays. Of these two means of indicating a faulted or normal circuit, the LED display is preferred by many technicians because of its high visibility, however, these fault indicators have the shortest operating lives of all fault indicators due to their relatively high energy consumption, when operating the LED display, and their relatively low energy capacity batteries.

Generally, there are high costs associated with the manufacturing of fault circuit indicators (FCI's). In most cases, a company involved with manufacturing FCI's needs to maintain documentation and inventory for hundreds of different fault indicator models, each with their own unique, model-specific printed circuit board assemblies. Also, the component count per printed circuit board assembly typically has a minimum of 60-100 discrete components. This overabundance of model-specific hardware coupled with the excessive component count results in high manufacturing costs.

The present invention represents a significant improvement over the prior art described above.

### SUMMARY OF THE INVENTION

The present invention provides, in at least one embodiment, a fault indicator powered by a capacitive power source. The capacitive power source can be a charged capacitor which can be charged by an electrostatic field and an electromagnetic field around a power line being monitored. The charged capacitor can be an electrochemical double-layer capacitor, a supercapacitor, or an ultracapacitor. These capacitors provide superior energy storage compared to conventional battery power sources.

In one embodiment of the invention, a device comprises: a clamp configured to clamp onto a power line; a capacitive power source attached to the clamp, wherein the capacitive power source receives power from the power line; and a display attached to the capacitive power source, wherein the display indicates a fault status of the power line. The capacitive power source may comprise an electrochemical double-layer capacitor, an ultracapacitor, or a supercapacitor. The capacitive power source may be configured to receive power from an electrostatic field and an electromagnetic field of the power line. The fault status may comprise a fault condition or a normal condition. The display may comprise an LED display or indicators. The device may further comprise a microprocessor attached to the capacitive power source and housing to house electronics, wherein the electronics may comprise power source circuitry, microprocessor circuitry, control circuitry, or display circuitry.

In another embodiment of the invention, a system comprises: a power line; a clamp configured to clamp onto the power line; a capacitive power source attached to the clamp, wherein the capacitive power source receives power from the power line; and a display attached to the capacitive power source, wherein the display indicates a fault status of the power line. The capacitive power source may comprise an electrochemical double-layer capacitor, an ultracapacitor, or a supercapacitor. The capacitive power source may be configured to receive power from an electrostatic field and an electromagnetic field of the power line.

In a further embodiment of the invention, a method comprises the steps of: clamping onto a power line; providing a capacitive power source, wherein the capacitive power source receives power from the power line; and using the capacitive power source to power a display, wherein the display indicates a fault status of the power line. The capacitive power source may comprise an electrochemical double-layer capacitor and the capacitive power source is configured to receive power from an electrostatic field and an electromagnetic field of the power line. The fault status may comprise a fault condition or a normal condition.

An advantage of the present invention, where the fault indicator has a larger charge capacity by using a supercapacitor as opposed to a battery, is that the fault indicator can now use an LED display and other power consuming features that previously led to problems. The longer life expectancy of the fault indicator provides more reliability. Also, the fault indicator can now use a brighter display making the fault status more visible. Another advantage is that the fault indicator can accommodate changes through both hardware and firmware, as opposed to just hardware.

The foregoing, and other features and advantages of the invention, will be apparent from the following, more particular description of the preferred embodiments of the invention, the accompanying drawings, and the claims.

### BRIEF DESCRIPTION OF THE DRAWINGS

For a more complete understanding of the present invention, and the advantages thereof, reference is now made to the ensuing descriptions taken in connection with the accompanying drawings briefly described as follows:

FIGS. 1-2 illustrate a perspective view of a fault indicator according to embodiments of the invention;

FIGS. 3-6 illustrate the top, bottom, right, and left views of the fault indicator according to embodiments of the invention;

FIG. 7-8 illustrate exploded perspective views of the fault indicator according to embodiments of the invention;

FIG. 9 illustrates an electrical distribution layout according to an embodiment of the invention;

FIG. 10 illustrates a schematic drawings of a microprocessor according to an embodiment of the invention; and

FIG. 11 illustrates a process of creating a fault status according to an embodiment of the invention.

### DETAILED DESCRIPTION OF EMBODIMENTS

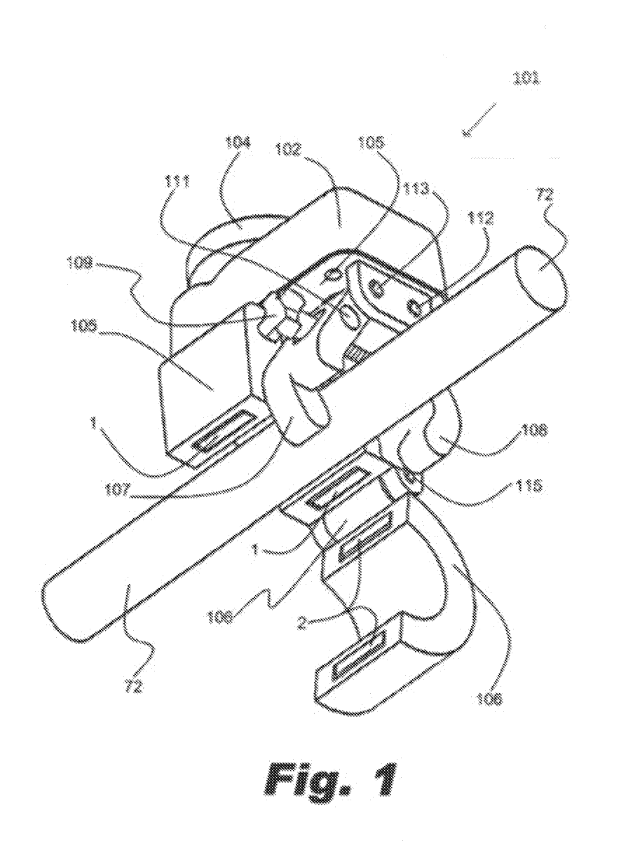

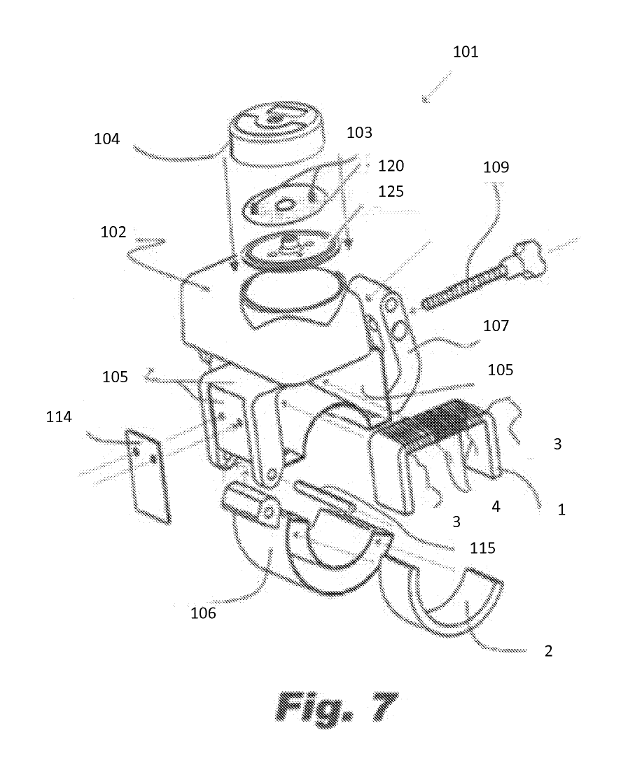

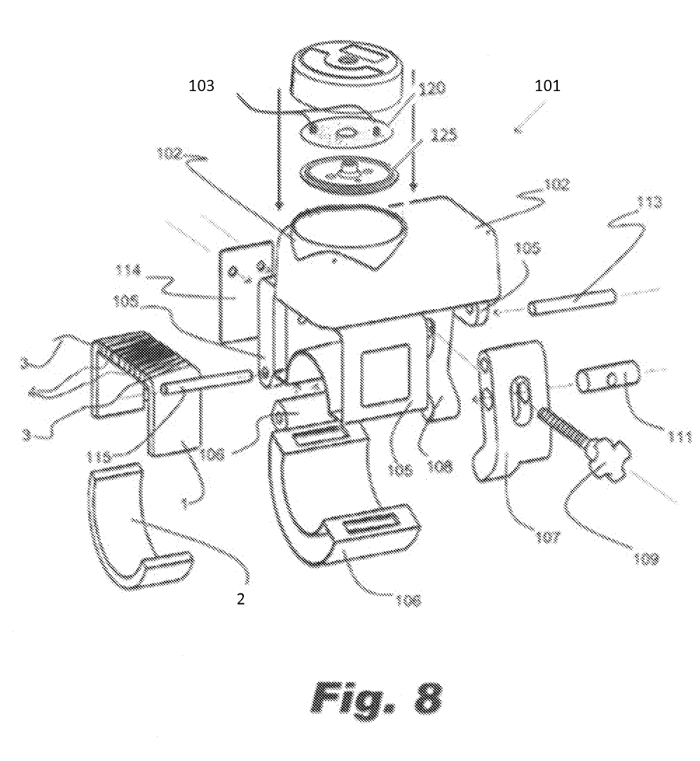

Further features and advantages of the invention, as well as the structure and operation of various embodiments of the invention, are described in detail below with reference to the accompanying FIGS. 1-11, wherein like reference numerals refer to like elements. Although the invention is described as implemented via a supercapacitor, one of ordinary skill in the art appreciates that other types of rechargeable capacitive power sources may be implemented. Further, although the capacitive power source uses a power line to power a fault indicator, the capacitive power source can also power many other electrical devices as well (e.g., a camera, wireless communication, etc.).

The present invention is direct to a fault indicator powered by a capacitive power source. The power source can be an inductive power supply that can easily and safely attach to a high voltage transmission line for retrieving low voltage, AC or DC power. The inductive power supply can utilize an inductor, which is also known as a current transformer, to retriever power from the transmission line. Energy storage components such as supercapacitors may be employed to store energy for later use. The electrical output of the power supply is a regulated low voltage output to power a load, e.g., sensitive electronics such as wireless devices and other microelectronics, coupled to the output of the power supply. The power supply further includes a sealed compartment for housing various types of low power devices coupled to the regulated low voltage output.

The supercapacitor can be comprised of several super cap cells arranged in parallel and series and controlled by the circuitry in power supply described also in the appendix of U.S. Provisional Application No. 61/410,766 and U.S. patent application Ser. No. 12/698,953, both of which this application has claimed priority to.

The capacitive power source (e.g., power supply) can be a charged capacitor or inductor which can be charged by an electrostatic field and/or an electromagnetic field of a power line being monitored. The charged capacitive power source can be an electrochemical double-layer capacitor, a supercapacitor, or an ultracapacitor, although these terms are sometimes used interchangeably. The capacitive power source provides superior energy storage compared to conventional battery power sources. Although the capacitive power source has a lower fully charged capacity, of about 0.0069 Ah, the capacitive power source has a total capacity of about 5,069 Ah since it can be re-charged 5,000 times (that is, 1.0138 Ah x 5,000 =5,069 Ah). The fault indicator using the capacitive power source provides a significant capacity improvement over existing power supply designs. For example, a capacitor's capacity of 5,069 Ah is over 500 times better than an 8.5 Ah battery (that is, 8.5 Ah×500<5,069 Ah).

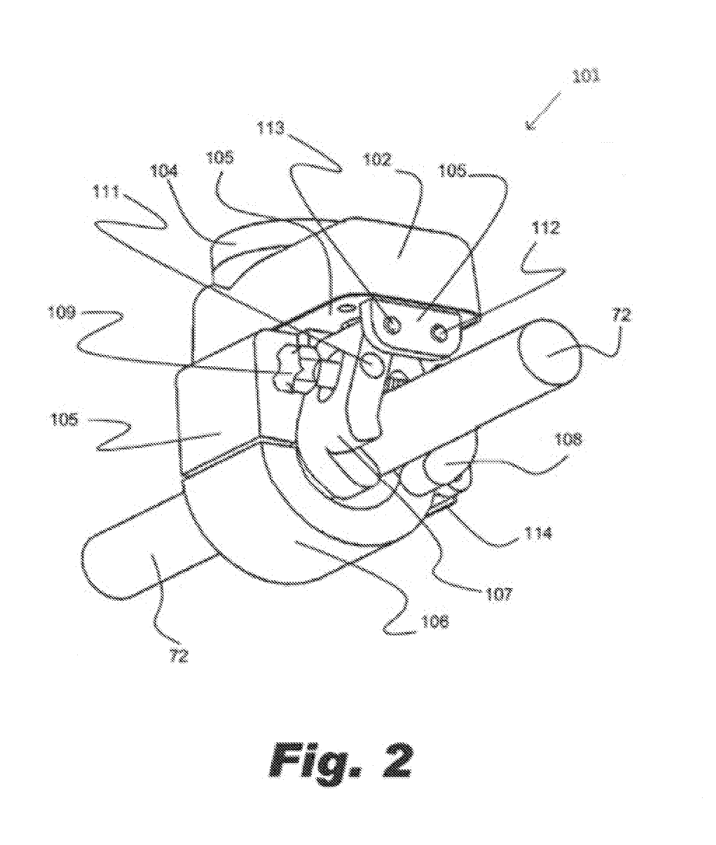

FIGS. 1-2 illustrate a perspective view of a fault indicator 101 according to embodiments of the invention. FIG. 1 shows the fault indicator 101 with a clamp 106 being open and FIG. 2 illustrates the fault indicator 101 with the clamp 106 being closed. The fault indicator 101 includes an enclosure 102, a display 104, a housing 105, the clamp 106 connectable with slots to an inductor 1 and a lock 2, sidings 107 and 108 enclosing a power line 72, a screw 109, a receptacle 111, an adaptor 112, a plug 113, a cover 114, and a conduit 115. The fault indicator 101 preferably receives power from the electrostatic field of the power line 72, although it is also possible for the fault indicator 101 to receive power from the electromagnetic field of the power line 72. The power is received through a supercapacitor, providing superior energy capacity. The fault indicator can be inductively coupled to the power line and electrostatically coupled to the power line.

The fault indicator 101 (e.g., faulted circuit indicator, FCI, etc.) indicates a fault condition, such that the LEDs begin flashing. The fault condition can be satisfied when three conditions are met: input voltage greater than a voltage (e.g., 10 mV) for an initialization time (e.g., 30 seconds, 3 minutes, etc.); a surge current detected, such as a power line current surge above a preset threshold (e.g., 200 amps, 500 amps, 800 amps, etc.), lasting longer than a given time (e.g., 1 msec, 4 msec, etc.); and a loss of power detected within a timeframe (e.g., 30 seconds) after the surge ends.

The fault indicator 101 can ignore inrush current, such that the warning display LED's do not flash, because inrush current is preceded by a de-energized power line. During the loss of power, the fault indicator 101 can be re-initializing and does not detect the over current caused by the inrush event.

The fault indicator 101 can also ignore power line overloading, even if the power line overloading exceeds the threshold of the fault indicator 101. This is because the power line did not become de-energized during the overloading event.

The enclosure 102, the housing 105, and the cover 114 provide structure, grounding, and protection for the electronics (e.g., power source circuitry, microcontroller circuitry, control circuitry, display circuitry, etc.) of the fault indicator 101. The display 104 (e.g., top cover, enclosure cover, etc.) reveals indicators that show the fault status. The display 104 can be an LED display with red and green LED indicators. The display can have a clear cover to protect the display and allow the LED indicators to be seen.

The clamp 106 surrounds the power line 72 (e.g., power cable). The clamp 106 can provide an attachment with the lock 2, such that the fault indicator 101 does not fall off the power line 72. Further structure can be provided by sidings 107 and 108, which enclose the power line 72. The screw 109 can tighten and loose the sidings 107 and 108 for a proper fit around the power line 72. The screw 109 passes through the receptacle 111 to hold the screw 109 in place. The clamp 106 can also have a conduit 115 that receives electrostatic and electromagnetic fields of the power line 72 or helps holds the power line 72 in place. The inductor 1 can receive this power and control the current into a microprocessor. The electrostatic and electromagnetic fields charge the supercapacitor. The adaptor 112 is configured to receive an external power source. The plug 113 is configured to provide power to external components.

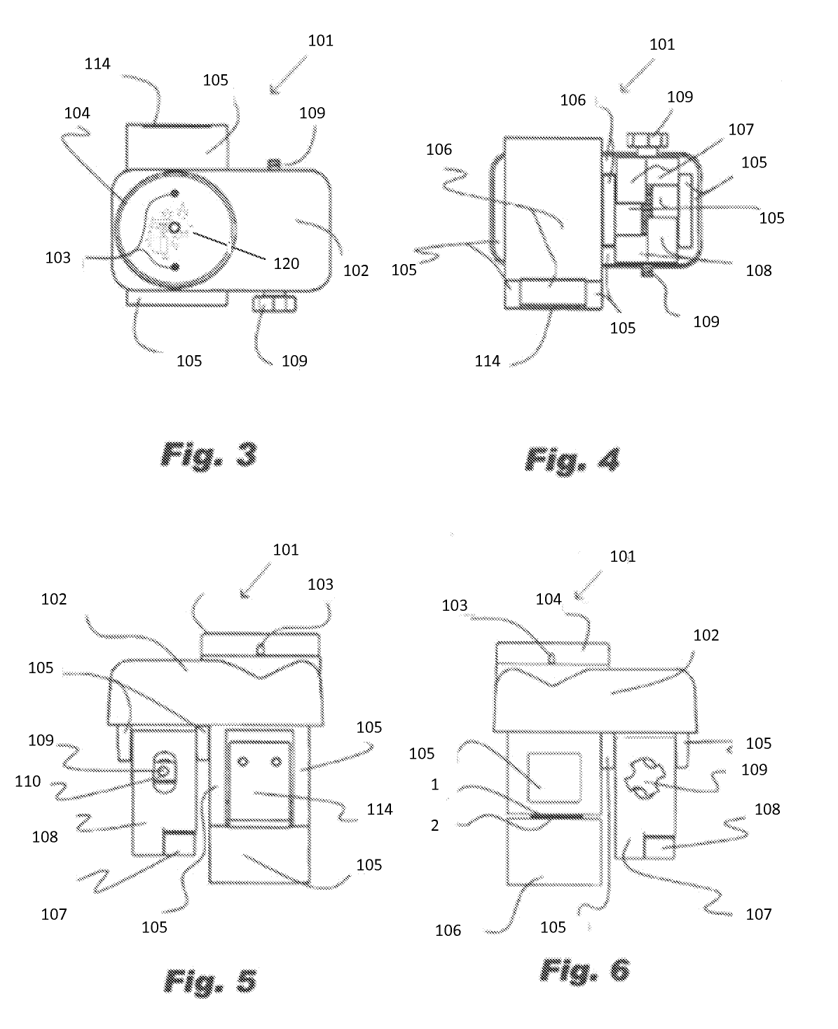

FIGS. 3-6 illustrate the top, bottom, right, and left views of the fault indicator 101 according to embodiments of the invention. The fault indicator 101 comprises indicators 103 (e.g., LED indicators) on a printed circuit board (PCB) 120 that are shown through the display/cover 104. The indicators 103 in the display 104 convey the fault status. The enclosure 102, housing 105, cover 114, and lock 2 enclose the electronics (e.g., power source circuitry, microprocessor circuitry, etc.), with the screw 109 for adjusting the sidings 107 and 108 around the power line 72. The clamp 106 encloses the power line 72. An opening 110 is shown for the screw 109 to penetrate through. The inductor 1 provides current to the microprocessor.

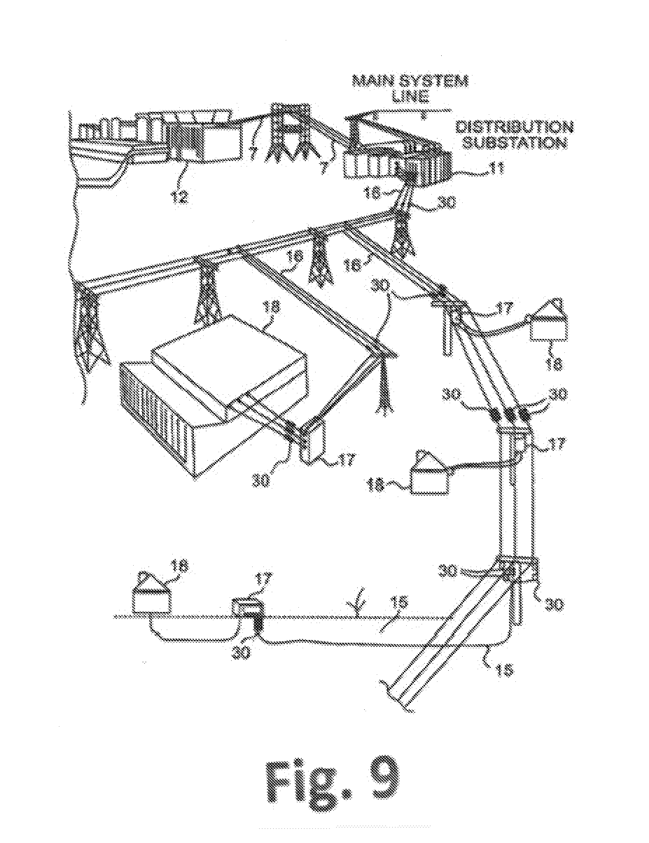

FIG. 7-8 illustrate exploded perspective views of the fault indicator 101 according to embodiments of the invention. The fault indicator 101 includes the enclosure 102, LED indicators 103 on the PCB 120, the display 104 (e.g., top cover), the housing 105, the clamp 106, the inductor 1 with wide windings 3 and narrow windings 4, the lock 2, the sidings 107 and 108, the screw 109, the receptacle 111, the plug 113, the cover 114, and the conduit 115. The PCB 120 attaches to an adapter 125 for connecting to the microprocessor.

FIG. 9 illustrates an electrical distribution layout according to an embodiment of the invention. The layout includes a main system line that passes power through a distribution substation through power lines to a consumer's home.

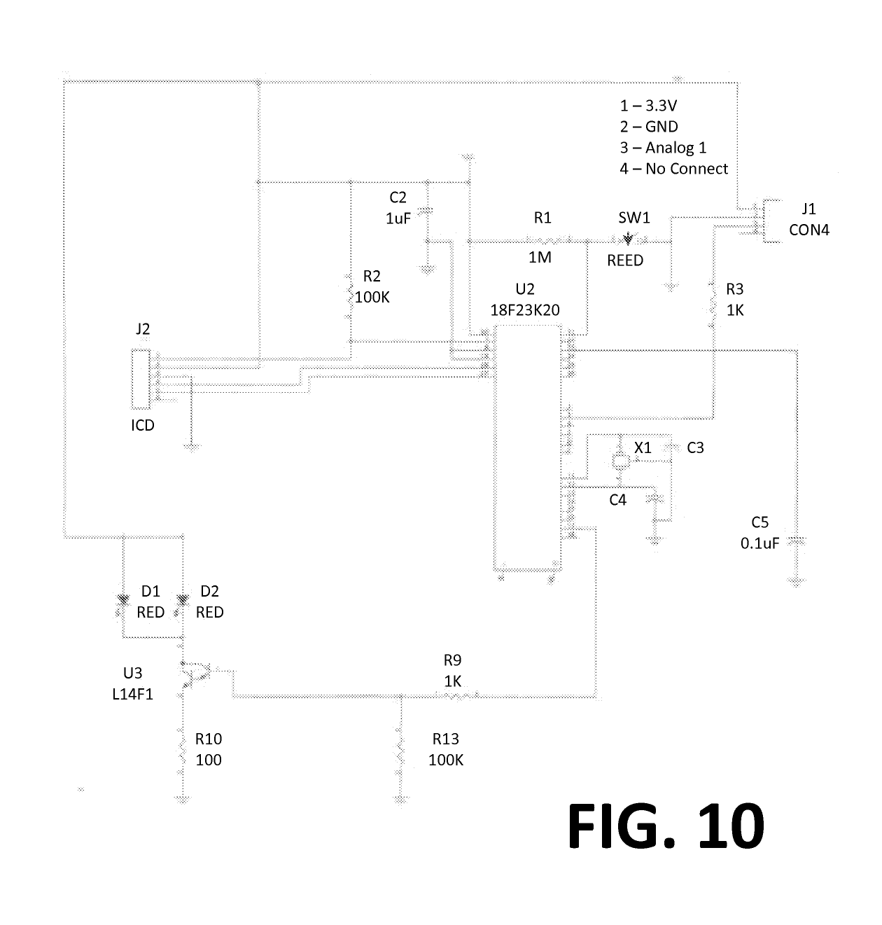

FIG. 10 illustrates a schematic drawing of a microprocessor (e.g., MCU, microcontroller, microcontroller unit, microprocessor control, etc.) according to an embodiment of the invention. The illustrated microprocessor comprises one or more a microprocessors, transistors, switches, LEDs, crystals, capacitors, male and female connectors, and resistors. The LEDs may comprise two red LEDs and/or one green LED. The male connector can be used for programming the microprocessor. In one embodiment, the microprocessor is electronic component part number PIC18F23K20.

The microprocessor (e.g., PIC18F23K20) can be programmed by a plethora of different and versatile firmware codes. In one embodiment, the microprocessor is programmed to have a 500 amp threshold with a four msec minimum trip response time and a four hour LED flash time out. In another embodiment, the microprocessor is programmed to have a 200 amp threshold with a 16 msec minimum trip response time and a two hour LED flash time out. In a further embodiment, the microprocessor is programmed to have an 800 amp threshold with a 24 msec minimum trip response time and a one hour LED flash time out.

In one embodiment, in order to indicate a fault condition, the fault indicator 101 requires a current surge of over 500 amps for longer than 4 msec on the power line and a loss of system power within 30 seconds. A loss of system power within 30 seconds indicates a fuse or circuit breaker has blown. If the power line does not lose power within 30 seconds, that means there was not a blown circuit breaker or fuse, and the power line simply received a current spike or surge, but did not have a fault condition.

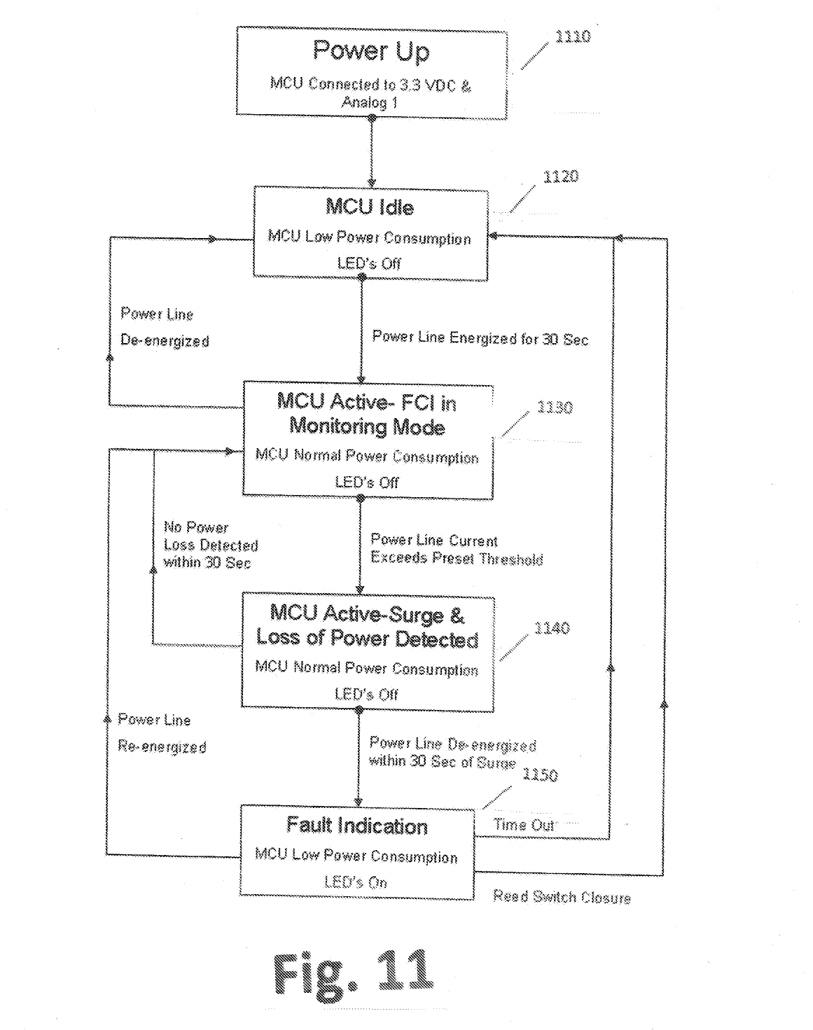

FIG. 11 illustrates a process of creating a fault status according to an embodiment of the invention. At step 1110, the power source powers up the microprocessor. The microprocessor can be powered by a DC and AC inputs. At step 1120, the microprocessor remains idle with the LED's off. If the power line is energized for 30 seconds, the process continues to step 1130 where the microprocessor is in active mode. An energized power line can be when the power line current is greater than 5 amps but less than a preset threshold. The preset threshold can be a factory preset current level (e.g., 200 amps, 500 amps, 800 amps, etc.) at which the fault circuit indicator will indicate a fault condition. If the power line is de-energized within 30 seconds, the microprocessor reverts back to idle mode at step 1120.

At step 1130, the fault indicator (e.g., faulted circuit indicator, FCI, etc.) is in monitoring mode. If the power line current exceeds the preset threshold, the process continues to step 1140 where the microprocessor is in an active-surge mode. At step 1140, the microprocessor is in an active-surge state. If no power loss is detected within 30 seconds, the microprocessor reverts back to active mode at step 1130. Alternatively, if power loss is detected within 30 seconds of the surge, the process continues to step 1150.

At step 1150, the fault indicator indicates a fault condition through the LED display. If the power line is re-energized, the microprocessor reverts back to active mode at step 1130. If the microprocessor times out, or if the reed switch is closed, the microprocessor reverts back to the idle mode at step 1120. A time out can be scheduled by a manufacture at a given time interval (e.g., 1 hour, 2 hours, 4 hours, etc.). The reed switch closure can be a reset switch, a manual reset, or an externally applied magnetic tool that activates the switch to reset the flashing LED display.

It is to be recognized that depending on the embodiment, certain acts or events of any of the methods described herein can be performed in a different sequence, may be added, merged, or left out altogether (for example, not all described acts or events are necessary for the practice of the method). Moreover, in certain embodiments, acts or events may be performed concurrently, for example, through multi-threaded processing, interrupt processing, or multiple processors, rather than sequentially.

The invention has been described herein using specific embodiments for the purposes of illustration only. It will be readily apparent to one of ordinary skill in the art, however, that the principles of the invention can be embodied in other ways. Therefore, the invention should not be regarded as being limited in scope to the specific embodiments disclosed herein, but instead as being fully commensurate in scope with the following claims.

What is claimed is:

1. A device comprising:
a clamp configured to clamp onto a power line;
a capacitive power source attached to the clamp, wherein the capacitive power source receives power from the power line; and
a display attached to the capacitive power source, wherein the display indicates a fault status of the power line.

2. The device of claim 1, wherein the capacitive power source comprises an electrochemical double-layer capacitor.

3. The device of claim 1, wherein the capacitive power source comprises an ultracapacitor.

4. The device of claim 1, wherein the capacitive power source comprises a supercapacitor.

5. The device of claim 1, wherein the capacitive power source is configured to receive power from an electrostatic field and an electromagnetic field of the power line.

6. The device of claim 1, wherein the fault status comprises a fault condition or a normal condition.

7. The device of claim 1, wherein the display comprises an LED display.

8. The device of claim 1, wherein the display comprises indicators.

9. The device of claim 1, further comprising a microprocessor attached to the capacitive power source.

10. The device of claim 1, further comprising a housing to house electronics.

11. The device of claim 10, wherein the electronics comprise power source circuitry, microprocessor circuitry, control circuitry, or display circuitry.

12. A system comprising:
a power line;
a clamp configured to clamp onto the power line;
a capacitive power source attached to the clamp, wherein the capacitive power source receives power from the power line; and
a display attached to the capacitive power source, wherein the display indicates a fault status of the power line.

13. The system of claim 12, wherein the capacitive power source comprises an electrochemical double-layer capacitor.

14. The system of claim 12, wherein the capacitive power source comprises an ultracapacitor.

15. The system of claim 12, wherein the capacitive power source comprises a supercapacitor.

16. The system of claim 12, wherein the capacitive power source is configured to receive power from an electrostatic field and an electromagnetic field of the power line.

17. A method comprising:
clamping onto a power line;
providing a capacitive power source, wherein the capacitive power source receives power from the power line; and
using the capacitive power source to power a display, wherein the display indicates a fault status of the power line.

18. The method of claim 17, wherein the capacitive power source comprises an electrochemical double-layer capacitor.

19. The method of claim 17, wherein the capacitive power source is configured to receive power from an electrostatic field and an electromagnetic field of the power line.

20. The method of claim 17, wherein the fault status comprises a fault condition or a normal condition.
